(19) United States
(12) Patent Application Publication
(10) Pub. No.: US 2005/0255713 A1
(43) Pub. Date: Nov. 17, 2005

(54) Method and apparatus for forming nitrided silicon film

(76) Inventors: Kohshi Taguchi, Kyoto (JP); Masahiro Yoshimoto, Kyoto (JP)

Correspondence Address: HARNESS, DICKEY & PIERCE, P.L.C., P.O. BOX 8910, RESTON, VA, 20195, US

(21) Appl. No.: 10/520,815

(22) PCT Filed: Jul. 4, 2003
(86) PCT No.: PCT/JP03/08552

§ 371 Date: Jan. 7, 2005

(30) Foreign Application Priority Data
Jul. 8, 2002 (JP) 2002-199122

(51) Int. Cl. C23C 16/00; H05H 1/24

(52) U.S. Cl. 438/792; 438/793; 118/723 R

(57) ABSTRACT

A method for forming a silicon nitride film which comprises heating a substrate (2) placed in the inner space (3) of a chamber (4) to a desired temperature, feeding a hexamethyl disilazane gas and a gas containing active species formed by the plasma excitation of an N₂ gas to the chamber (4) holding the substrate (2), to thereby deposit a reaction product formed by the reaction of the hexaalkyldisilazan gas with the above active species and form the silicon nitride film. The method allows the formation of a silicon nitride film being reduced in the contents of carbon and hydrogen with safety and good efficiency.

### TECHNICAL FIELD

The present invention relates to a method and apparatus for forming a silicon nitride film that is provided as an insulating film or a protective film on a surface of, for example, an integrated circuit board.

### BACKGROUND ART

Since a large number of electrodes are formed on an integrated circuit board, an insulating film for providing isolation between the electrodes, or a protective film, that is, a so-called passivation film, for protecting the circuit from, for example, moisture in the air are formed on the board. For example, in a MOSFET (metal-oxide-semiconductor field effect transistor), which is a type of semiconductor integrated circuit board, a silicon oxide (SiO₂) film that is formed by thermally oxidizing a silicon wafer is conventionally used as a gate insulator. However, since the density of the silicon oxide film is poor, when different types of materials are laminated, constituent elements of the different types of materials are likely to diffuse into the silicon oxide film as impurities, and accordingly there arises such a problem that, the impurities diffuse into the silicon oxide film and reach the substrate or the electrodes and the semiconductor performance is deteriorated. Furthermore, the dielectric constant of the silicon oxide film is about 4.0, and accordingly there arises a problem that when the silicon oxide film is used, for example, as a gate insulator in a MOSFET, the gate capacity is small.

Examples of techniques for solving these problems include a method in which a silicon nitride film is used instead of the silicon oxide film. The density of the silicon nitride film is higher than that of the silicon oxide film. Furthermore, the silicon nitride film has a high dielectric constant of about 7.5, and has an excellent resistance to humidity. Thus, the silicon nitride film is not only suitable for an insulator film that is used instead of the silicon oxide film, but also suitable for a passivation film.

Examples of conventional techniques for forming such a silicon nitride film on a substrate include thermal CVD (chemical vapor deposition) in which a silicon nitride film is formed by deposition of silicon nitride on a substrate using hexamethyldisilazane gas and ammonia gas (see Japanese Unexamined Patent Publication JP-A-2001-23904), and plasma CVD (PECVD: plasma enhanced CVD) in which a high frequency voltage is applied to a mixed gas including a monosilane compound, an organic silane compound, and a nitrogen compound so as to be plasma-excited, so that a silicon nitride film is formed by deposition of silicon nitride as a reaction product thereof on a substrate (see Japanese Unexamined Patent Publication JP-A07-106256(1995)).

These conventional techniques have problems as below. In the thermal CVD process in Japanese Unexamined Patent Publication JP-A-2001-23904, the silicon nitride thin film is formed by a chemical reaction at high temperature Thus, in light of productivity, it is necessary to heat the reactant gas and the substrate to a high temperature of 900° C. to 1000° C. or more. When a semiconductor integrated circuit board is used as the substrate, for example, since the upper temperature limit for some semiconductors is about 700° C. to B00° C., the thermal CVD process damages the semiconductor integrated circuits themselves too seriously to be used, although a silicon nitride film can be formed. Thus, the thermal CVD process can be used only for limited types of substrates.

In the PECVD process in Japanese Unexamined Patent Publication JP-A 7-106256 (1995), the substrate itself is not damaged unlike in the thermal CVD process, since the thin film can be formed at a temperature of about 200° C. to 400° C. However, all of the monosilane compound, the organic silane compound and the nitrogen compound are plasma-excited, and as a part of the reaction product, hydrogen (H) that is generated by the dissociation of the monosilane compound, and carbon (C) and H that are generated by the dissociation of the organic silane compound are mixed into the silicon nitride film that is deposited on the substrate. When the silicon nitride film contains a large amount of H, the chemical bond therein becomes unstable. Thus, for example, an etching performance of a wet etching in a photolithographic process for producing semiconductor device becomes unstable, and it becomes impossible to perform accurate patterning. Furthermore, when the silicon nitride film contains a large amount of C, it becomes impossible to use the film as an insulator film, because C makes the film conductive, and thus the insulating performance of the film is deteriorated.

Of these problems, examples of techniques for preventing a silicon nitride film from containing C at least include a method for depositing a silicon nitride film on a substrate using the PECVD process with a mixed gas including monosilane (SiH₄), nitrogen (N₂), and ammonia (NH₃). When using this method, the raw material gas does not contain C, and thus the silicon nitride film does not contain C. However, monosilane has such a strong explosivity that it explodes only by being brought in contact with oxygen in the air. Therefore, general PECVD apparatuses can not be used for forming a silicon nitride film, and it is necessary to use an extremely expensive PECVD apparatus with various accessory equipment with safety measures. Furthermore, since monosilane has the explosivity as described above, a person who can perform an operation for forming a silicon nitride film is limited only to operators who are skilled in handling monosilane.

The monosilane is thus difficult to handle, and accordingly a remote plasma system has been proposed in which a silicon carbon nitride film is formed using hexamethyldisilazane that is easy to handle, instead of using the monosilane (see Hatanaka, Kitamura, S. Wickramanayaka, Nakanishi, and J. Tyczkowsky, “Remote Plasma deposition of SiCxNy film using hexamethyldisilazane,” Proc. of 6th Int. Conf. Silicon Carbide and Related Materials Kyoto, IOP Conf Ser. No. 142, 1995, p. 1055-1058). However, the technique disclosed in this document is basically a technique for forming a silicon carbon nitride film, and thus it is impossible to prevent the formed film from containing C. Furthermore, a result of an analysis on the formed film composition shows that the film contains CH₃ as well. More specifically, in the remote plasma system disclosed in this document, the hexamethyldisilazane is degraded by plasmas, and C and H, which are constituent elements thereof, are mixed into the formed film.

As described above, C deteriorates the insulating performance, and H deteriorates the etching performance. Therefore, according to the technique proposed in this document in which the formed film contains C and H, it is impossible to form a silicon nitride film that is excellent in insulating performance and protection performance for integrated circuit boards.

### DISCLOSURE OF INVENTION

An object of the invention is to provide a method and apparatus for forming a silicon nitride film, capable of safely and effectively forming a silicon nitride film containing less carbon and hydrogen.

The invention is a method for forming a silicon nitride film, including:
accommodating a substrate in an internal space of a chamber;
supplying hexaalkyldisilazane (CₙH₂ₙ₊₁)₃SiNHSi(CₙH₂ₙ₊₁)₃) gas and a gas including a nitrogen compound that is plasma-excited to the chamber accommodating the substrate; and
depositing a reaction product of the hexaalkyldisilazane gas and the gas including a nitrogen compound that is plasma-excited on the substrate to form a silicon nitride film.

According to the invention, a silicon nitride film is formed in such a manner that the gas including a nitrogen compound that is plasma-excited and the hexaalkyldisilazane gas that is not plasma-excited are supplied to the substrate that is accommodated in the chamber, and a reaction product is generated by reacting active species formed by plasma-excitation of the nitrogen compound with the hexaalkyldisilazane in the vicinity of the substrate is deposited on the substrate. In this specification, “nitrogen compound” refers to a compound including N atoms as constituent atoms, and includes N₂ consisting only of N atoms.

Since the hexaalkyldisilazane that is a silicon (Si) supplying source for a silicon nitride film is supplied to the chamber without being plasma-excited by supplying the hexaalkyldisilazane gas and the gas including a nitrogen compound that is plasma-excited to the chamber in such a manner that the pressure in the region in which the nitrogen compound is plasma-excited is higher than the pressure in the region in which the reaction product is generated in the vicinity of the substrate, the hexaalkyldisilazane is dissociated by energy transfer with the active species formed by plasma-excitation of the nitrogen compound in the vicinity of the substrate. The dissociated Si reacts with the active species to generate a reaction product. Thus, C and H contained in the hexaalkyldisilazane are not activated excessively, and it is possible to reduce the amount of C and H contained in the silicon nitride film deposited on the substrate. Furthermore, since the hexaalkyldisilazane is not dangerous such as being explosive, the silicon nitride film can be formed safely, and the operators handling the hexaalkyldisilazane are not limited.

Furthermore, the invention is characterized in that the substrate is heated to room temperature to 800° C.

According to the invention, the substrate is heated to room temperature to 800° C., and thus the energy transfer between the active species formed by plasma-excitation of the nitrogen compound and the hexaalkyldisilazane in the vicinity of the substrate and the generation of the reaction product are promoted, and as a result, the silicon nitride film is further effectively deposited on the substrate.

Furthermore, the invention is characterized in that the hexaalkyldisilazane is hexamethyldisilazane {(CH₃)₃SiNHSi(CH₃)₃}.

According to the invention, the hexaalkyldisilazane is hexamethyldisilazane (hereinafter abbreviated as HMDS). HMDS is suitable as a material used in PECVD process, since HMDS is not explosive, and is easy to evaporate due to its high vapor pressure though HMDS is a liquid at normal temperature. Furthermore, HMDS is not corrosive to metals, so that HMDS does not corrode aluminum (Al), copper (Cu), or the like that is used, for example, for wiring of the substrate, and thus HMDS does not damage the substrate performance or the substrate life. Moreover, since HMDS is produced industrially, for example, as an adhesive improver for a photoresist that is used in a photolithographic process for producing semiconductors, HMDS is available easily and inexpensively.

Furthermore, the invention is characterized in that the nitrogen compound is constituted by a gas including at least one of N₂ and NH₃.

According to the invention, the nitrogen compound that is plasma-excited is constituted by a gas including at least one of N₂ and NH₃. Since N₂ and NH₃ are available easily and inexpensively, it is possible to expand the versatility of this method for forming a silicon nitride film. In this specification, the gas including at least one of N₂ and NH₃ is constituted by a gas that includes N₂ and/or NH₃ as essential components, and further includes at least one selected from the group consisting of H₂, He, Ar, Xe, Ne, and the like.

Furthermore, the invention is an apparatus for forming a silicon nitride film on a surface of a substrate, including:
a chamber in which the substrate is accommodated in its internal space;
first gas supplying means for supplying hexaalkyldisilazane gas to the internal space of the chamber;
second gas supplying means for supplying gas including a nitrogen compound to the internal space of the chamber; and
plasma excitation means that is provided in the second gas supplying means, for plasma-exciting the gas including a nitrogen compound supplied to the internal space of the chamber.

According to the invention, the apparatus for forming a silicon nitride film is provided with the chamber in which the substrate is accommodated in its internal space, the first gas supplying means for supplying hexaalkyldisilazane gas to the internal space of the chamber, the second gas supplying means for supplying gas including a nitrogen compound to the internal space of the chamber, and the plasma excitation means for plasma-exciting the gas including a nitrogen compound that is supplied to the internal space of the chamber.

In the apparatus for forming a silicon nitride film, gas including a nitrogen compound that is plasma-excited and hexaalkyldisilazane gas that is not plasma-excited are supplied to the chamber that accommodates the substrate, and a reaction product generated by reacting active species formed by plasma-excitation of the nitrogen compound with the hexaalkyldisilazane gas is deposited on the substrate. Thus, a silicon nitride film is formed. In this manner, by the use of the hexaalkyldisilazane that is not dangerous such as being explosive and the nitrogen compound that is plasma-excited, it is possible to realize an apparatus for forming a silicon nitride film that is inexpensive because of its excellent safety and no need of unwanted accessory equipment, and has high productivity.

Furthermore, the invention is characterized in that a gas supplying portion of the second gas supplying means for supplying gas to the internal space of the chamber has an orifice structure.

According to the invention, the gas supplying portion of the second gas supplying means has an orifice structure, and thus the pressure in the gas supplying portion becomes higher than the pressure in the internal space of the chamber. Consequently, the pressure of the hexaalkyldisilazane gas supplied from the first gas supplying means to the internal space of the chamber is lower than the pressure of the gas, including a nitrogen compound that is supplied from the gas supplying portion with the orifice structure, and thus the hexaalkyldisilazane gas is prevented from flowing from the internal space back to the second gas supplying means.

On the other hand, since the plasma excitation means is provided in the second gas supplying means, the plasma excitation means is prevented from dissociating the hexaalkyldisilazane gas that does not flow back to the second gas supplying means. Therefore, C and H that constitute the hexaalkyldisilazane gas are inhibited from being mixed into the silicon nitride film, and t is possible to form a silicon nitride film that has the excellent insulating performance and the protection performance for an integrated circuit board.

Furthermore, the invention is characterized in that heating means for heating the substrate is further provided.

According to the invention, the heating means for heating the substrate is further provided. The heating means can heat the substrate, for example, to room temperature to 800° C. Thus, an apparatus for forming a silicon nitride film can be realized by which the energy transfer between the active species formed by plasma excitation of the nitrogen compound and the hexaalkyldisilazane in the vicinity of the substrate and the generation of the reaction product are promoted, and thus the silicon nitride film is further, effectively deposited on the substrate.

Furthermore, the invention is characterized in that the hexaalkyldisilazane is hexamethyldisilazane (HMDS), and that the nitrogen compound is constituted by a gas including at least one of N₂ and NH₃.

According to the invention, the hexaalkyldisilazane supplied to the apparatus for forming a silicon nitride film is HMDS, and the nitrogen compound includes at least one of N₂ and NH₃, Since it is possible to use a reactant gas that is produced industrially and is available easily, such as HMDS and N₂ or NH₃, an apparatus for forming a silicon nitride film with high versatility can be provided.

### BRIEF DESCRIPTION OF THE DRAWINGS

Other and further objects, features, and advantages of the invention will be more explicit from the following detailed description taken with reference to the drawings wherein:

FIG. 1 shows a simplified configuration of an apparatus 1 for forming a silicon nitride film according to an embodiment of the invention;

FIG. 2 shows an enlarged view of a second spray nozzle 24 in second gas supplying means 6;

FIG. 3 is a flow chart illustrating an operation for forming a silicon nitride film on a substrate 2 using the apparatus 1 for forming a silicon nitride film;

FIG. 4 shows a result of analysis by XPS on Si in the silicon nitride film;

FIG. 5 shows a result of analysis by XPS on N in the silicon nitride film;

FIG. 6 shows a result of analysis by FT-IR on the silicon nitride film; and

FIG. 7 shows are results of analysis by XPS on C (carbon) in the silicon nitride film.

### BEST MODE FOR CARRYING OUT THE INVENTION

Now referring to the drawings, preferred embodiments of the invention are described below.

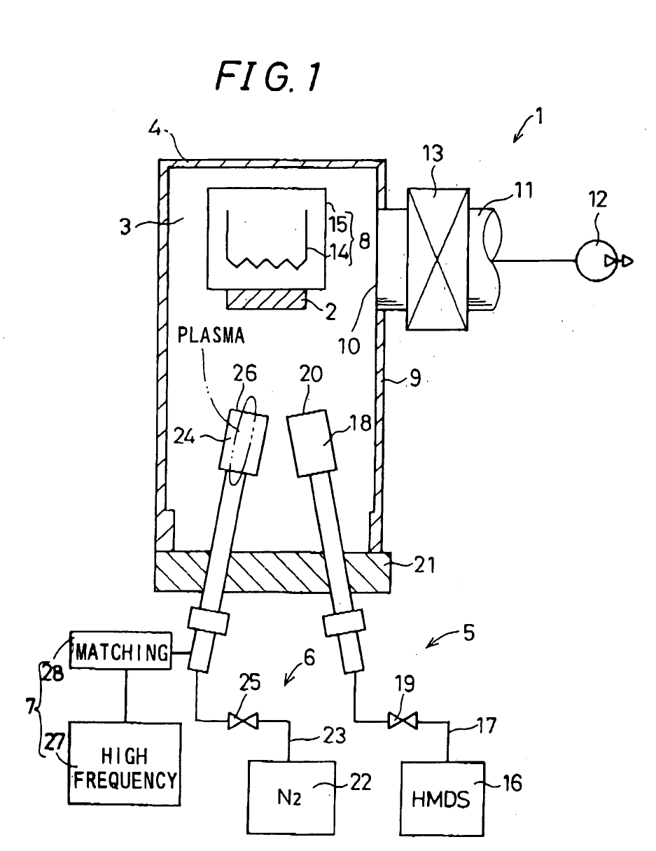

FIG. 1 shows a simplified configuration of an apparatus 1 for forming a silicon nitride film according to an embodiment of the invention. The apparatus 1 for forming a silicon nitride film is provided with a chamber 4 in which a substrate 2 is accommodated in its internal space 3, first gas supplying means 5 for supplying HMDS gas to the internal space 3 of the chamber 4, second gas supplying means 6 for supplying N₂ gas to the internal space 3 of the chamber 4, plasma excitation means 7 that is provided in the second gas supplying means 6 and that plasma-excites the N₂ gas supplied to the internal space 3 of the chamber 4, and heating means 8 for heating the substrate 2.

The chamber 4 might be a chamber that is made of, for example, stainless steel, that is substantially rectangular solid, and that is hollow and airtight. Through a side wall portion 9 on one side of the chamber 4, a vent 10 is formed for evacuating the internal space 3. A vent pipe 11 is connected to the vent 10, and a vacuum pump 12 (turbomolecular pump) is connected to a tip edge of the vent pipe 11 on the opposite side of the vent 10. A shutter 13 is provided between the vacuum pump 12 of the vent pipe 11 and the vent 10 of the chamber 4. By opening the shutter 13 and operating the vacuum pump 12, it is possible to evacuating the internal space 3 so as to reduce the pressure. Furthermore, by closing the shutter 13, it is possible to seal up the internal space 3 of the chamber 4. The chamber 4 is also provided with a door (not shown in FIG. 1) that opens and closes freely, so that the substrate 2 can move into/out from the internal space 3 through the door.

The substrate 2 that is accommodated in the internal space 3 of the chamber 4 and on which a silicon nitride film is to be formed is, for example, a silicon substrate that is a silicon wafer on which a circuit is formed. The heating means 6 for heating the substrate 2 includes a heater 14, a heat conducting member 15 that conducts heat generated by the heater 14 to the substrate 2, and a control power source (not shown) that supplies electric power to the heater 14 and that controls on/off of the electric power supply. The heater 14 uses a resistance heating element such as a nichrome wire. The substrate 2 is mounted in contact with the heat conducting member 15, and heated by the heater 14 via the heat conducting member 15 to a desired temperature ranging from room temperature to 800° C.

The control power source may control the temperature of the substrate 2, for example, by controlling the conduction time based on a predetermined operation program. It is also possible to provide a temperature sensor in the vicinity of an area where the substrate 2 is mounted on the heat conducting member 15, and to input the output value detected by the heat sensor into the control power source, for feedback control for its on/off.

In this embodiment, HMDS {(CH₃)₃SiNHSi(CH₃)₃} that is hexaalkyldisilazane {(CₙH₂ₙ₊₁)₃SiNHSi(CₙH₂ₙ₋₁)₃} is used as a silicon (Si) source for a silicon nitride film. The first gas supplying means 5 for supplying HMDS to the internal space 3 of the chamber 4 is provided with an HMDS supplying source 16 that stores HMDS, a first pipe 17 through which the HMDS gas flows from the HMDS supplying source 16 to the chamber 4, a first spray nozzle 18 that is provided so as to be connected to an end portion of the first pipe 17 on the downstream side in the direction of the flow, and spray the HMDS gas toward the vicinity of the substrate 2 accommodated in the internal space 3, and a pressure/flow rate regulator 19 that is provided in the first pipe 17 between the HMDS supplying source 16 and the first spray nozzle 18, and that adjusts the pressure and the flow rate of the HMDS gas.

The HMDS supplying source 16 is, for example, a sealed-up cylindrical container, in which liquid HMDS is stored and evaporated HMDS with a vapor pressure is present in the space above the liquid. The first spray nozzle 18 is secured at a flange-shaped base plate 21 constituting the chamber 4 so that an ejection opening 20 is opposed to the substrate 2 and the HMDS gas sprayed from the ejection opening 20 is supplied to the vicinity of the substrate 2. The HMDS gas is sprayed and supplied from the first nozzle 18 to the vicinity of the substrate 2 in such a manner that, by opening the pressure/flow rate regulator 19, the HMDS gas is drawn into the internal space 3 that has low pressure because the internal space 3 has been evacuated by the vacuum pump 12. The flow rate of the supplied HMDS gas is adjusted by the degree of opening of the pressure/flow rate regulator 19.

In this embodiment, the HMDS is supplied in such a manner that the HMDS gas that has evaporated inside the HMDS supplying source 16 is drawn into the chamber 4 utilizing its high vapor pressure. However, the invention is not limited to this, and it is also possible to blow, for example, nitrogen (N₂) gas into the HMDS supplying source 16 to cause bubbling, and the blown N₂ gas is used as carrier gas so that the HMDS gas is supplied to the chamber 4.

In this embodiment, N₂ gas is used as a nitrogen (N) compound that is a nitrogen source for a silicon nitride film. The second gas supplying means 6 for supplying N₂ gas to the internal space 3 of the chamber 4 is provided with an N₂ supplying source 22 that stores N₂ gas, a second pipe 23 through which the N₂ gas flows from the N₂ supplying source 22 to the chamber 4, a second spray nozzle 24 that is provided so as to be connected to an end portion of the second pipe 23 on the downstream side in the direction of the flow, and spray the N₂ gas toward the vicinity of the substrate 2 accommodated in the internal space 3, and a pressure/flow rate regulator 25 that is provided in the second pipe 23 between the N₂ supplying source 22 and the second nozzle 24, and that adjusts the pressure and the flow rate of the N₂ gas.

The N₂ supplying source 22 is, for example, a sealed-up cylindrical container, in which liquid N₂ gas is stored. The second spray nozzle 24 is secured at the flange-shaped base plate 21 constituting the chamber 4 so that an ejection opening 26 is opposed to the substrate 2 and the N₂ gas sprayed from the ejection opening 26 is supplied to the vicinity of the substrate 2. The flow rate of the supplied N₂ gas is adjusted by the degree of opening of the pressure/flow rate regulator 25.

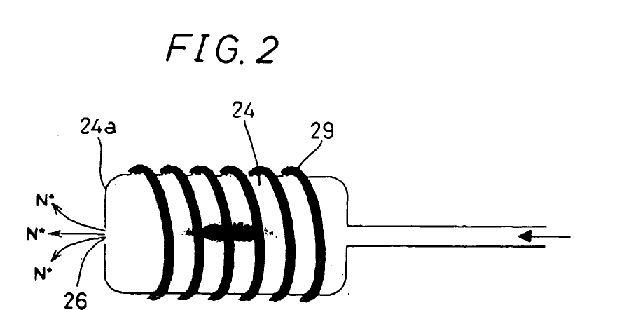

FIG. 2 shows an enlarged view of the second spray nozzle 24 in the second gas supplying means 6. As shown in FIG. 2, the second spray nozzle 24 that is a gas supplying portion in the second gas supplying means 6 has an orifice structure. In the second spray nozzle 24, the ejection opening 26 that is formed at an edge portion 24a opposed to the substrate 2 is an opening through which N₂ gas, which is a fluid, is sprayed from the second spray nozzle 24, that is, an orifice. Thus, in the second spray nozzle 24, the pressure in the orifice portion that is the ejection opening 26 supplying N₂ gas to the internal space 3 of the chamber 4 becomes higher than the pressure in the internal space 3 of the chamber 4, that is, the pressure of the HMDS supplied from the first gas supplying means 5 to the internal space 3.

The plasma excitation means 7 is connected to the vicinity of an end portion of the second spray nozzle 24 on the side of the second pipe 23. The plasma excitation means 7 includes a high-frequency oscillator 27 and a matching unit 28. The plasma excitation means 7 is provided with an inductively coupled P. F. cell. A high frequency voltage that is generated by the plasma excitation means 7 is applied to a helical antenna 29 that is provided at the second spray nozzle 24, so that the N₂ gas that flows through the second spray nozzle 24 is plasma-excited, and then active species (denoted by N* in FIG. 2) are formed. Thus, to be exact, the N₂ gas that is sprayed and supplied from the ejection opening 26 of the second spray nozzle 24 to the vicinity of the substrate 2 includes the active species that are formed by plasma excitation.

As described above, the pressure of the HMDS supplied from the first gas supplying means 5 to the internal space 3 is lower than the pressure of the N₂ gas that includes the active species and that is supplied from the second spray nozzle 24 with the orifice structure, and thus the HMDS gas is prevented from flowing from the internal space 3 back to the second spray nozzle 24. Therefore, the plasma excitation means 7 does not excite or dissociate the HMDS gas.

The HMDS that is supplied from the first spray nozzle 18 to the vicinity of the substrate 2 is dissociated by receiving an energy from the active species that are formed by plasma excitation and are supplied from the second spray nozzle 24 to the vicinity of the substrate 2. Si that is formed by the HMDS dissociation further reacts with the active species, and then the reaction product is deposited on the surface of the substrate 2, so that a silicon nitride film is formed. The HMDS is dissociated, not directly by plasma excitation, but by receiving energy from the active species, and thus C or H generated by the HMDS dissociation is not activated excessively.

In this manner, the apparatus 1 for forming a silicon nitride film is characterized in that only the N source, which is one component of the silicon nitride film, is supplied while being plasma-excited, whereas the HMDS as the Si source, which is the other component of the silicon nitride film, is supplied without being plasma-excited.

In general PECVD apparatuses, a pair of electrodes are provided in their chamber for discharging within the chamber, so that all of N₂ gas, NH₃ gas, and HMDS that are supplied into the chamber are plasma-excited. Therefore, although the deposition efficiency of the silicon nitride film is excellent, the HMDS is also plasma-excited, so that C and H as well as Si are similarly activated and deposited on the surface of the substrate 2 as the reaction product of the active species. The silicon nitride film that is formed in this manner is contaminated with C and H, so that the film performance is deteriorated.

However, in the apparatus 1 for forming a silicon nitride film of the invention, the N source that is plasma-excited and the HMDS as the Si source that is not plasma-excited can be segregated and be supplied separately, as described above. Therefore, C and H contained in the HMDS are inhibited from being activated, and thus the amount of C and H contained in the silicon nitride film that is formed as the reaction product is decreased. Furthermore, although the N₂ gas as the N source is plasma-excited, the HMDS as the Si source is not plasma-excited. Thus, the invention maintains the higher deposition efficiency of the silicon nitride film than thermal CVD process, although the deposition efficiency is slightly decreased compared with the case in which both the N source and the Si source are plasma-excited.

The composition of the silicon nitride film that is formed by the apparatus 1 for forming a silicon nitride film is substantially Si₃N₄. However, it is possible to control the composition ratio between Si and N of this silicon nitride film, by adjusting the flow rate ratio between the HMDS and the N₂ gas that are supplied to the vicinity of the substrate 2. Furthermore, the apparatus 1 for forming a silicon nitride film supplies Si and N, which are components of a silicon nitride film, by the first and second gas supplying means 5 and 6. Thus, when forming the silicon nitride film, a reaction with Si of the substrate is not an essential requirement. Therefore, the substrate need not contain Si, and thus the substrate for forming a silicon nitride film is not limited to a silicon wafer, and substrates having other compositions, such as gallium arsenic (GaAs) also can be used.

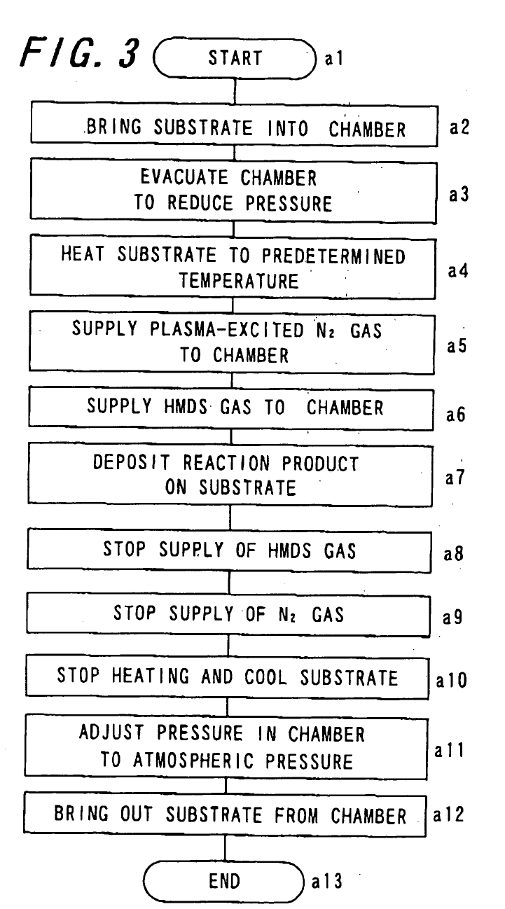

FIG. 3 is a flow chart illustrating an operation for forming a silicon nitride film on the substrate 2 using the apparatus 1 for forming a silicon nitride film. The operation for forming a silicon nitride film on the substrate 2 will be described with reference to FIG. 3.

In Step a1 as the start, the apparatus 1 for forming a silicon nitride film is prepared, and HMDS and N₂ gas are prepared at the first and second gas supplying means 5 and 6. In Step a2, the substrate 2 is brought into the internal space 3 of the chamber 4, and is mounted on a predetermined position of the heat conducting member 15. In Step a3, the shutter 13 is opened and the vacuum pump 12 is operated, so as to evacuate the chamber 4. The degree of vacuum in the chamber 4 is adjusted by the degree of opening of the shutter 13, to attain a predetermined pressure.

In Step a4, the substrate 2 is heated to a predetermined temperature by the heating means 8. It is possible to heat the substrate 2 before the HMDS gas and the N₂ gas are supplied. In Step a5, the N₂ gas that is plasma-excited by the plasma excitation means 7 is supplied to the chamber 4 by the second gas supplying means 6. Herein, to be exact, the N₂ gas includes the active species that are formed by plasma excitation. In Step a6, the HMDS gas is supplied to the chamber 4 by the first gas supplying means 5.

In Step a7, the substrate 2 is heated and the HMDS gas and the N₂ gas are supplied continuously until the time elapses that is set based on the relationship between the deposition thickness and the processing time of the silicon nitride film that was obtained in advance. Then, the reaction product of the HMDS gas and the active species formed by plasma excitation is deposited on the surface of the substrate 2, so that a silicon nitride film is formed. In Step a8, the supply of the HMOS gas to the chamber 4 is stopped. In Step a9, the supply of the N₂ gas to the chamber 4 is stopped. In Step a10, after the predetermined time elapses, the heating of the substrate 2 is stopped, and then the substrate is cooled.

In Step a11, for example, an air open valve (not shown in FIG. 1) provided at the chamber 4 is opened, so that the pressure in the chamber 4 is adjusted to atmospheric pressure. In Step a12, the substrate 2 is brought out from the chamber 4, and then in Step a13, the series of operation for forming a silicon nitride film is ended.

### EXAMPLE

Hereinafter, an example of the invention will be described.

The apparatus 1 for forming a silicon nitride film was prepared, and a silicon nitride film was formed on a silicon wafer substrate using HMDS as the Si source and N₂ gas as the N source of the silicon nitride film. Table 1 shows the conditions used when forming the silicon nitride film. The volume of the internal space 3 of the chamber 4 provided in the forming apparatus 1 was substantially 1000 L (liters).

TABLE 1

| Pressure in chamber | 1 × 10⁻⁷ Torr | |
|---|---|---|
| (in evacuation) | (about 1.3 × 10⁻⁵ Pa) | |
| HMDS gas flow rate | 1.0 | mL/min |
| N₂ gas flow rate | 1.0 | mL/min |
| Heating temperature of silicon wafer | 700° C. | |
| High-frequency oscillation power | 250 | W |
| Oscillating frequency | 13.56 | MHz |

Under the conditions shown in Table 1, a reaction product of HMDS gas and active species formed by plasma-excitation of N₂ gas was deposited on the silicon wafer continuously for 3 hours, so that a silicon nitride film was formed. The composition of the formed silicon nitride film was measured by XPS (X-ray photoelectron spectroscopy) and FT-IR (Fourier Transform Infra Red). Furthermore, the dielectric constant of the silicon nitride film was measured by an impedance meter (manufactured by WAYNEKERR; Precision Component Analyzer 6425), and the refractive index was measured by an ellipsometer (manufactured by Mizojiri Optical Co., Ltd.; DVA-FL Type).

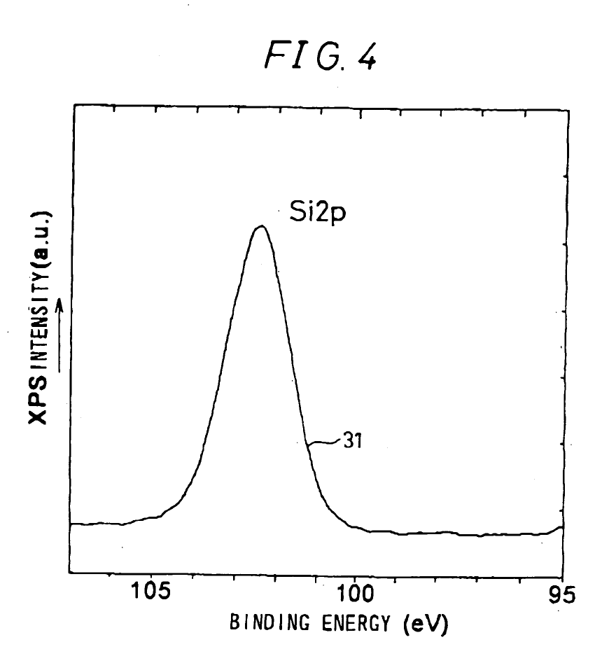

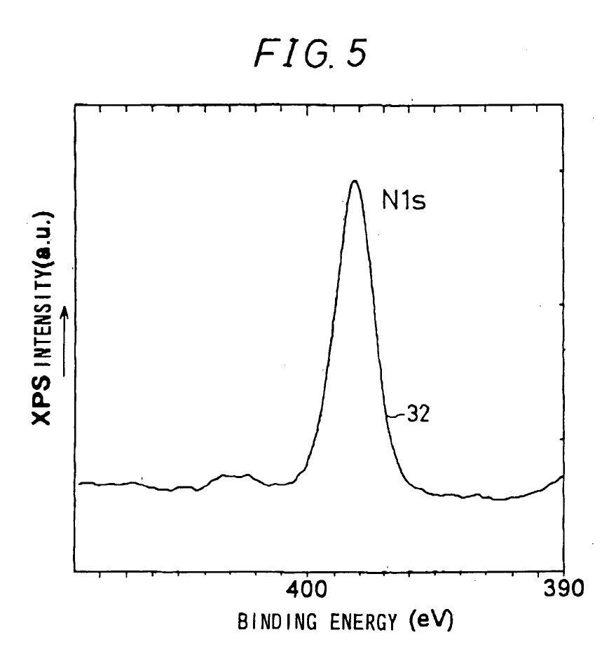

FIG. 4 shows a result of the analysis by XPS on Si in the silicon nitride film, and FIG. 5 shows a result of the analysis by XPS on N in the silicon nitride film. As clearly shown by a line 31 in FIG. 4, an eminent peak was seen in a binding energy that indicates the presence of Si. Similarly, as clearly shown by a line 32 in FIG. 5, an eminent peak was seen in a binding energy that indicates the presence of N. Therefore, it was confirmed that the film formed on the silicon wafer contained Si and N, that is, a silicon nitride film was formed.

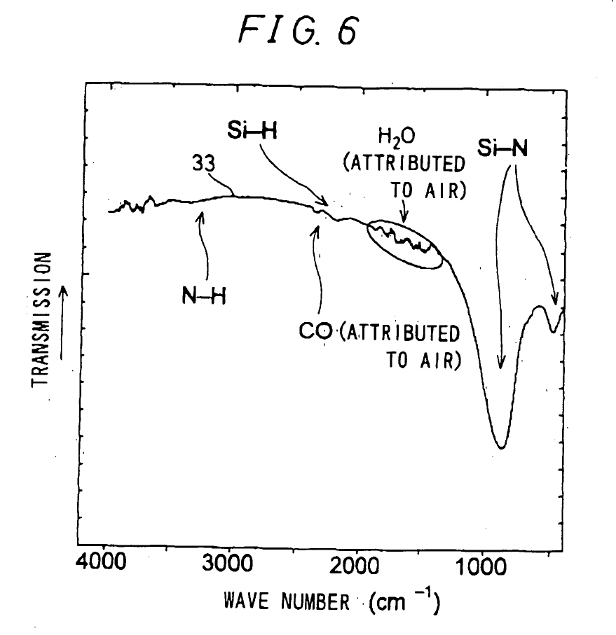

FIG. 6 shows a result of the analysis by FT-IR on the silicon nitride film. In the result of the analysis by the FT-IR on the silicon nitride film, the wave number is shown on the horizontal axis, and the transmission is shown on the vertical axis, The spectrum indicated by the line 33 in FIG. 6 is the result of the analysis. The spectrum shows that bonds of Si—N are present in the silicon nitride film. Furthermore, the spectrum shows that H is slightly present. On the other hand, C—H was below the limit of detection of the FT-IR. When a film contains C—H, the film becomes significantly unstable and likely to be changed over time in terms of the film characteristics. Additionally, the film density becomes lower. The silicon nitride film that was deposited according to the present method was a dense film that is hardly changed over time.

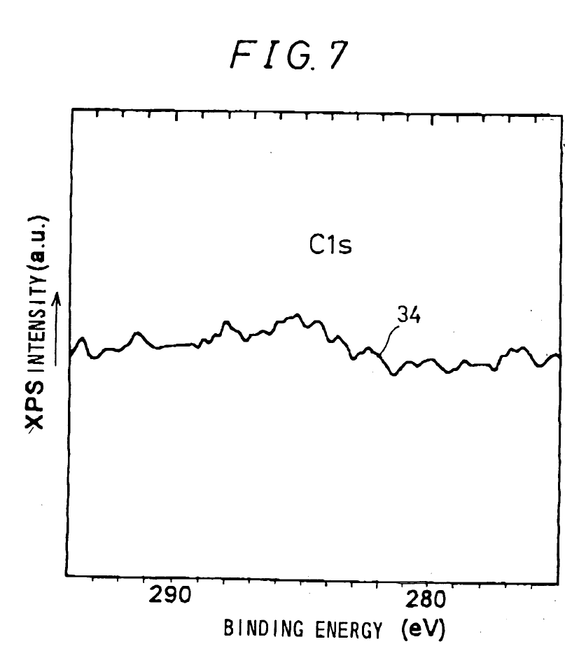

FIG. 7 shows a result of the analysis by XPS on C (carbon) in the silicon nitride film. As shown by a line 34, C was not observed, that is, C was little mixed into the film.

The dielectric constant of the silicon nitride film was 7.6, which is a better value than the dielectric constant of other insulating films such as a silicon oxide film, which has a dielectric constant of 4. The refractive index thereof was 1.8 to 2.0. By adjusting the ratio between the flow rates of the HMDS gas and the N₂ gas when forming a silicon nitride film, it is possible to adjust the composition ratio between Si and N in the silicon nitride film, so that the refractive index can be controlled to some extent. By forming a silicon nitride film that has a desirable refractive index in this manner, it is expected that the film can be used as an optical element forming, for example, a wave guide.

As described above, HMDS is used as the Si source of the silicon nitride film in the embodiment. However, the invention is not limited to this, and it is possible to use other organic silane compounds that belong to hexaalkyldisilazane. Furthermore, N₂ is used as the nitrogen compound. However, the invention is not limited to this, and it is possible to use NH₃, or a gas including at least one selected from the group consisting of H₂, He, Ar, Xe, Ne, and the like, in addition to N₂ and/or HN₃. Although, means for applying a high frequency electric field for discharging is used as the plasma excitation means 7, the invention is not limited to this, and it is possible to use other means. Although the substrate 2 is heated by the heating means 8, it is also possible not to heat the substrate 2. However, in order to improve the deposition efficiency of the silicon nitride film even slightly, it is preferable to heat the substrate 2.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

### INDUSTRIAL APPLICABILITY

According to the invention, gas including a nitrogen compound that is plasma-excited and hexaalkyldisilazane gas that is not plasma-excited are supplied to a substrate that is accommodated in a chamber, and a reaction product generated by reacting active species formed by plasma excitation of the nitrogen compound with the hexaalkyldisilazane gas is deposited on the substrate. Thus, a silicon nitride film is formed.

In this manner, the hexaalkyldisilazane as a silicon source of the silicon nitride film is supplied without being plasma-excited. Thus, the hexaalkyldisilazane is dissociated by energy transfer with the active species formed by plasma-excitation of the nitrogen compound in the vicinity of the substrate. The dissociated Si reacts with the active species to generate a reaction product. Thus, C and H contained in the hexaalkyldisilazane are not activated excessively, and it is possible to reduce the amount of C and H contained in the silicon nitride film deposited on the substrate. Furthermore, since the hexaalkyldisilazane is not dangerous such as being explosive, the silicon nitride film can be formed safely, and the operators handling the hexaalkyldisilazane are not limited.

Furthermore, according to the invention, the substrate is heated to room temperature to 800° C. Consequently, the energy transfer between the active species formed by plasma-excitation of the nitrogen compound and the hexaalkyldisilazane in the vicinity of the substrate and the generation of the reaction product are promoted, and thus the silicon nitride film is further effectively deposited on the substrate.

Furthermore, according to the invention, the hexaalkyldisilazane is HMDS. HMDS is suitable as a material used in PECVD process, since HMDS is not explosive, and is easy to evaporate due to its high vapor pressure although HMDS is a liquid at normal temperature. Furthermore, HMDS is not corrosive to metals, so that HMDS does not corrode Al, Cu, or the like that is used, for example, for wiring of the substrate, and thus HMDS does not damage the substrate performance or the substrate life. Moreover, since HMDS is industrially produced, for example, as an adhesive improver for a photoresist that is used in a photolithographic process for producing semiconductors, HMDS is available easily and inexpensively.

Furthermore, according to the invention, the nitrogen compound that is plasma-excited is constituted by a gas including at least one of N₂ and NH₃. Since N₂ and NH₃ are available easily and inexpensively, it is possible to expand the versatility of this method for forming a silicon nitride film.

Furthermore, according to the invention, an apparatus for forming a silicon nitride film is provided with a chamber in which a substrate is accommodated in its internal space, first gas supplying means for supplying hexaalkyldisilazane gas to the internal space of the chamber, second gas supplying means for supplying gas including a nitrogen compound to the internal space of the chamber, and plasma excitation means for plasma-exciting the gas including a nitrogen compound that is supplied to the internal space of the chamber.

In the apparatus for forming a silicon nitride film, gas including a nitrogen compound that is plasma-excited and hexaalkyldisilazane gas that is not plasma-excited are supplied to the chamber that accommodates the substrate, and a reaction product generated by reacting active species formed by plasma-excitation of the nitrogen compound with the hexaalkyldisilazane gas is deposited on the substrate. Thus, a silicon nitride film is formed. In this manner, by the use of the hexaalkyldisilazane that is not dangerous such as being explosive and the nitrogen compound that is plasma-excited, it is possible to realize an apparatus for forming a silicon nitride film that is inexpensive because of its excellent safety and no need of unwanted accessory equipment, and has high productivity.

Furthermore, according to the invention, a gas supplying portion of the second gas supplying means has an orifice structure. Thus, the pressure in the gas supplying portion becomes higher than the pressure in the internal space of the chamber. Consequently, the pressure of the hexaalkyldisilazane gas supplied from the first gas supplying means to the internal space of the chamber is lower than the pressure of the gas including a nitrogen compound that is supplied from the gas supplying portion with the orifice structure, and thus the hexaalkyldisilazane gas is prevented from flowing from the internal space back to the second gas supplying means.

On the other hand, since the plasma excitation means is provided in the second gas supplying means, the plasma excitation means is prevented from dissociating the hexaalkyldisilazane gas that does not flow back to the second gas supplying means. Therefore, C and H that constitute the hexaalkyldisilazane gas are inhibited from being mixed into the silicon nitride film, and it is possible to form a silicon nitride film that has the excellent insulating performance and the protection performance for an integrated circuit board.

Furthermore, according to the invention, heating means for heating the substrate is further provided. The heating means can heat the substrate, for example, to room temperature to 800° C. Thus, an apparatus for forming a silicon nitride film can be realized by which the energy transfer between the active species formed by plasma-excitation of the nitrogen compound and the hexaalkyldisilazane in the vicinity of the substrate and the generation of the reaction product are promoted, and thus the silicon nitride film is deposited on the substrate further effectively.

Furthermore, according to the invention, the hexaalkyldisilazane supplied to the apparatus for forming a silicon nitride film is HMDS, and the nitrogen compound supplied to the same includes at least one of N₂ and NH₃. Since it is possible to use a reactant gas that is industrially produced and is available easily, such as HMDS and N₂ or NH₃, an apparatus for forming a silicon nitride film with high versatility can be provided.

1. A method for forming a silicon nitride film, comprising:
accommodating a substrate in an internal space of a chamber;
supplying hexaalkyldisilazane [(CₙH₂ₙ₊₁)₃SiNHSi(CₙH₂ₙ₊₁)₃] gas and a gas including a nitrogen compound that is plasma-excited to the chamber accommodating the substrate; and
depositing a reaction product of the hexaalkyldisilazane gas and the gas including a nitrogen compound that is plasma-excited on the substrate to form a silicon nitride film.

2. The method of claim 1, wherein the substrate is heated to room temperature to 800° C.

3. The method of claim 1, wherein the hexaalkyldisilazane is hexamethyldisilazane [(CH₃)₃SiNHSi(CH₃)₃].

4. The method of claim 1, wherein the nitrogen compound is constituted by a gas including at least one of N₂ and NH₃.

5. An apparatus for forming a silicon nitride film on a surface of a substrate, comprising:
a chamber in which the substrate is accommodated in its internal space;
first gas supplying means for supplying hexaalkyldisilazane gas to the internal space of the chamber;
second gas supplying means for supplying gas including a nitrogen compound to the internal space of the chamber; and
plasma excitation means that is provided in the second gas supplying means, for plasma-exciting the gas including a nitrogen compound supplied to the internal space of the chamber.

6. The apparatus of claim 5, wherein a gas supplying portion of the second gas supplying means for supplying gas to the internal space of the chamber has an orifice structure.

7. The apparatus of claim 5, wherein heating means for heating the substrate is further provided.

8. The apparatus of claim 5, wherein the hexaalkyldisilazane is hexamethyldisilazane, and the nitrogen compound is constituted by a gas including at least one of N₂ and NH₃.

9. The method of claim 2, wherein the hexaalkyldisilazane is hexamethyldisilazane [(CH₃)₃SiNHSi (CH₃)₃].

10. The method of claim 2, wherein the nitrogen compound is constituted by a gas including at least one of N₂ and NH₃.

11. The method of claim 3, wherein the nitrogen compound is constituted by a gas including at least one of N₂ and NH₃.

12. The apparatus of claim 6, wherein heating means for heating the substrate is further provided.

13. The apparatus of claim 6, wherein the hexaalkyldisilazane is hexamethyldisilazane, and the nitrogen compound is constituted by a gas including at least one of N₂ and NH₃.

14. The apparatus of claim 7, wherein the hexaalkyldisilazane is hexamethyldisilazane, and the nitrogen compound is constituted by a gas including at least one of N₂ and NH₃.
